(19) United States
(12) Patent Application Publication
(10) Pub. No.: US 2025/0267790 A1
(43) Pub. Date: Aug. 21, 2025

(54) PCB AND MANUFACTURING METHOD THEREFOR

(71) Applicant: SHENZHEN TCL NEW TECHNOLOGY CO., LTD., Shenzhen, Guangdong (CN)

(72) Inventor: Jinle LI, Shenzhen, Guangdong (CN)

(73) Assignee: SHENZHEN TCL NEW TECHNOLOGY CO., LTD., Shenzhen, Guangdong (CN)

(21) Appl. No.: 18/857,820

(22) PCT Filed: Jan. 16, 2023
(86) PCT No.: PCT/CN2023/072376

§ 371 Date: Oct. 18, 2024

(30) Foreign Application Priority Data
Apr. 18, 2022 (CN) 202210402742.1

(51) Int. Cl. H05K 1/11; H05K 1/05; H05K 3/32

(52) U.S. Cl. CPC H05K 1/115; H05K 1/05; H05K 3/32; H05K 2201/09509; H05K 2201/10242

(57) ABSTRACT

A printed circuit board (PCB) and a manufacturing method thereof are provided. The PCB includes a metal substrate, an insulating layer, a circuit layer, and a connector. The insulating layer is disposed on a side of the metal substrate, and is provided with a through hole. The circuit layer is disposed on a side of the insulating layer away from the metal substrate. The connector is disposed in the through hole to electrically connect the metal substrate and the circuit layer.

This application claims priority to Chinese Patent Application No. 202210402742.1, filed Apr. 18, 2022 and entitled “PCB AND MANUFACTURING METHOD THEREFOR”. The entire disclosures of the above application are incorporated herein by reference.

### TECHNICAL FIELD

The present application relates to the field of PCBs, and in particular to a PCB and a manufacturing method therefor.

### BACKGROUND TECHNOLOGY

In a process of PCB mounting, one or both of wave soldering and reflow soldering are usually required. The wave soldering is to solder components by forming a solder wave with molten solder. The reflow soldering is to solder components by forming a reflow of melted solder with high-temperature hot air.

In ordinary PCB single-sided boards, small SMD components are attached to a copper surface with glue, connected with bare copper wires, and then wave soldered together after installing plug-in components. However, aluminum substrate PCBs do not have plug-in components, and all components are mounted on a copper surface, connected with bare copper wires, and then reflow soldered together.

### SUMMARY OF INVENTION

### Technical Problem

At present, LEDs used in lighting, TV backlighting and other fields generally use an aluminum substrate PCB as a mounting carrier. In particular, in the field of TV backlighting, as the number of lamp beads used increases and distribution becomes more dense, a circuit design becomes more and more complicated. Circuits on the PCB are becoming more and more complicated. A bare copper wire is required for cross-line connection, while wave soldering is required for the cross-line connection of the bare copper wire. The cross-line connection of the bare copper wire can simplify layout and routing on the PCB. However, since an installation of large component patches cannot be done by the wave soldering, it can only be done by reflow soldering of the aluminum substrate PCB, which cannot ensure reliable contact between the bare copper wire and the aluminum substrate.

### Technical Solutions

An embodiment of the present application provides a PCB, including:
a metal substrate;
an insulating layer disposed on a side of the metal substrate, and provided with a through hole;
a circuit layer disposed on a side of the insulating layer away from the metal substrate;
a connector disposed in the through hole to electrically connect the metal substrate and the circuit layer.

In some embodiments, the circuit layer is provided with a first hole, the first hole is communicated with the through hole, the connector is disposed in the first hole, one end of the connector abuts against the metal substrate, and another end of the connector abuts against the circuit layer to electrically connect the metal substrate and the circuit layer.

In some embodiments, the first hole is a first blind hole, and an opening direction of the first blind hole is toward the insulating layer.

In some embodiments, the first hole is a first through hole.

In some embodiments, a diameter of the first through hole is greater than a diameter of the through hole.

In some embodiments, the metal substrate is provided with a second hole, the second hole is communicated with the through hole, the connector is disposed in the second hole, one end of the connector abuts against the metal substrate, and another end of the connector abuts against the circuit layer to electrically connect the metal substrate and the circuit layer.

In some embodiments, the second hole is a second blind hole, and an opening direction of the second blind hole is toward the insulating layer.

In some embodiments, the second hole is a second through hole.

In some embodiments, a diameter of the second through hole is greater than a diameter of the through hole.

In some embodiments, the connector is a metal rivet, the metal rivet includes a rivet head and a rivet rod, the metal rivet is disposed in the through hole, the rivet head abuts against the circuit layer, and the rivet rod abuts against the metal substrate to electrically connect the metal substrate and the circuit layer.

In some embodiments, a surface of the rivet head abutting against the circuit layer is an inclined surface, and a thickness of the rivet head gradually decreases from close to the rivet rod toward away from the rivet rod.

In some embodiments, a material of the connector is the same as a material of the metal substrate.

In some embodiments, the connector and the metal substrate are integrally formed.

As a second aspect of embodiments of the present disclosure, an embodiment of the present disclosure provides a PCB manufacturing method, the method includes:
providing a metal substrate;
disposing an insulating layer on the metal substrate, where the insulating layer is provided with a through hole;
disposing a connector in the through hole, where the connector abuts against the metal substrate;
disposing a circuit layer on a side of the insulating layer away from the metal substrate, where the circuit layer abuts against the connector such that the metal substrate and the circuit layer are electrically connected.

In the manufacturing method of some embodiments, the circuit layer is provided with a first hole, the first hole is communicated with the through hole, the connector is disposed in the first hole, one end of the connector abuts against the metal substrate, and another end of the connector abuts against the circuit layer to electrically connect the metal substrate and the circuit layer.

In the manufacturing method of some embodiments, the first hole is a first blind hole, and an opening direction of the first blind hole is toward the insulating layer.

In the manufacturing method of some embodiments, the first hole is a first through hole.

In the manufacturing method of some embodiments, the metal substrate is provided with a second hole, the second hole is communicated with the through hole, the connector is disposed in the second hole, one end of the connector abuts against the metal substrate, and another end of the connector abuts against the circuit layer to electrically connect the metal substrate and the circuit layer.

In the manufacturing method of some embodiments, the second hole is a second blind hole, and an opening direction of the second blind hole is toward the insulating layer.

As a third aspect of embodiments of the present disclosure, an embodiment of the present disclosure provides a PCB manufacturing method, the method includes:
laminating a metal substrate, an insulating layer, and a circuit layer in sequence to form a metal substrate PCB;
forming a through hole, where the through hole at least extends through the insulating layer;
disposing a connector in the through hole, where the connector abuts against the metal substrate and the circuit layer to electrically connect the metal substrate and the circuit layer.

### Beneficial Effects

In the embodiments of the present application, a reliable electrical connection between the metal substrate and the circuit layer is achieved by the connector abutting against the circuit layer and the connector contacting the metal substrate. In addition, in the embodiments of the present application, a size of the connector is slightly larger than the diameter of the through hole. When the connector is disposed in the through hole, the connector and the through hole have an interference fit, and the through hole can firmly fix the connector, ensuring the stability of the connector in the through hole. Therefore, the PCB provided in the embodiments of the present application ensures a reliable and stable connection between the circuit layer and the metal substrate, which is conducive to realizing a more complex circuit layout of the metal substrate PCB.

### BRIEF DESCRIPTION OF THE DRAWINGS

Technical solutions and beneficial effects of the present application will be made apparent by describing in detail specific implementation methods of the present application in conjunction with accompanying drawings.

FIG. 1 is a schematic diagram of a structure of a PCB when a through hole is provided on an insulating layer of an embodiment of the present application.

FIG. 2 is a schematic diagram of a structure of a PCB when a through hole is provided on a circuit layer of an embodiment of the present application.

FIG. 3 is a schematic diagram of a structure of a PCB when a blind hole is provided on a metal substrate of an embodiment of the present application.

FIG. 4 is a schematic diagram of a structure of a PCB when a through hole is provided on a PCB of an embodiment of the present application.

FIG. 5 is another schematic diagram of a structure of a PCB when a through hole is provided on a PCB of an embodiment of the present application.

FIG. 6 is another schematic diagram of a structure of a PCB when a through hole is provided on a PCB of an embodiment of the present application.

### DETAILED DESCRIPTION OF THE EMBODIMENTS

The technical solutions in the embodiments of the present application will be described clearly and completely below in conjunction with the drawings in the embodiments of the present application. Apparently, the described embodiments are only a part of the embodiments of the present application, rather than all of the embodiments. Based on the embodiments in the present application, all other embodiments obtained by those skilled in the art without creative efforts are within the scope of protection of the present application.

An embodiment of the present application provides a PCB 100, which may be, for example, a PCB 100 of an LED (light-emitting diode) backlight panel.

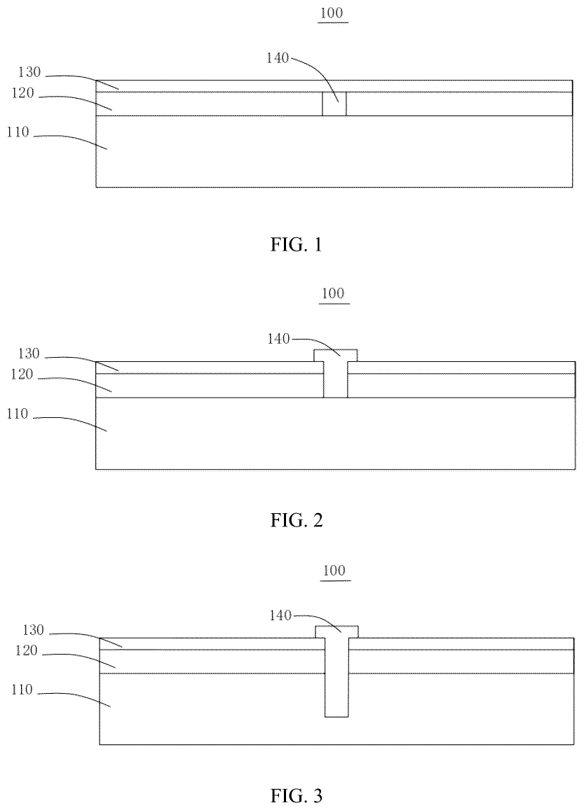

Please refer to FIG. 1, which is a schematic diagram of a structure of the PCB 100 when a through hole is provided on an insulating layer 120 according to an embodiment of the present application.

The PCB 100 includes a metal substrate 110, an insulating layer 120, a circuit layer 130, and a connector 140.

The PCB 100 uses a metal substrate as a substrate, and metal has good thermal conductivity. Therefore, the PCB 100 using the metal substrate as a substrate has a good heat dissipation performance. For example, the metal substrate can be an aluminum substrate, it can be a copper substrate, etc.

An insulating layer 120 is disposed on a side of the metal substrate 110. The insulating layer 120 may be formed of an epoxy glass cloth bonding sheet, or may be formed of a highly thermally conductive epoxy resin or other resin, or may be formed of a polyolefin resin or polyimide resin glass prepreg. Users may select a suitable material as the insulating layer 120 according to an application scenario of the PCB 100, and no limitation is made here.

Furthermore, as shown in FIG. 1, the insulating layer 120 is provided with a through hole. Position, shape, number, and size of the through hole can be selected and set according to an actual application scenario, and are not specifically limited here. For example, the through hole can be set in a middle, or in four corners, etc. For example, the through hole can be a circular hole, or a square hole, etc. For example, the number of the through holes can be one, or four, or six, etc.

The circuit layer 130 is disposed on a side of the insulating layer 120 facing away from the metal substrate 110. The circuit layer 130 may be a copper foil layer, an aluminum foil layer, an aluminum alloy foil layer, or a copper alloy foil layer. In this embodiment, the circuit layer 130 is an example of a copper foil layer, but the copper foil layer cannot be used as a limitation of the embodiments of the present application.

The connector 140 is disposed in the through hole to electrically connect the metal substrate 110 and the circuit layer 130. It is understood that the connector 140 is made of a conductive material, for example, the connector 140 can be made of a metal element, such as copper, aluminum, etc.; or an alloy, such as aluminum alloy, iron, copper alloy, etc.; or a composite metal.

In addition, it should be noted that a structural size of the connector 140 is very important, because its structural size not only affects the reliability of the electrical connection between the metal substrate 110 and the circuit layer 130, but also affects the reliability and automation performance in the production process. In order to ensure that the connector 140 can stably abut against the metal substrate 110 and the circuit layer 130 to electrically connect the metal substrate 110 and the circuit layer 130, the size of the connector 140 should be slightly larger than a diameter of the through hole. When the connector 140 is placed in the through hole, the connector 140 and the through hole have an interference fit, and the through hole can well fix the connector 140. The connector 140 is prevented from moving in the through hole, which may cause incomplete contact between the connector 140 and the metal substrate 110 and the circuit layer 130, thereby making it impossible for the connector 140 to electrically connect the metal substrate 110 and the circuit layer 130.

In this embodiment, after the insulating layer 120 is provided with the through hole, the connector 140 is placed in the through hole. The metal substrate 110 and the circuit layer 130 are electrically connected by the interference fit between the connector 140 and the through hole, thereby ensuring a reliable connection between the connector 140 and the metal substrate 110, and facilitating the realization of a more complex circuit layout of a metal substrate PCB.

In one embodiment, as shown in FIG. 2, the circuit layer 130 is provided with a first hole. The first hole is communicated with the through hole. The connector 140 is provided in the first hole. One end of the connector 140 abuts against the metal substrate 110, and the other end of the connector 140 abuts against the circuit layer 130 to electrically connect the metal substrate 110 and the circuit layer 130.

In one embodiment, the first hole is a first blind hole. An opening direction of the first blind hole is toward the insulating layer 120. It is understandable that a length of the connector 140 is longer than a depth of the through hole. When the connector 140 is placed in the through hole, a portion of the connector 140 extending out of the through hole extends into the first blind hole. In order to prevent an unstable connection between the connector 140 and the circuit layer 130 from causing the metal substrate 110 and the circuit layer 130 to be unable to be electrically connected, the size of the connector 140 should be slightly larger than the diameter of the first blind hole. The portion of the connector 140 extending into the first blind hole is interference-fitted with the first blind hole, which can effectively ensure the reliability of the connection between the connector 140 and the circuit layer 130.

In addition, the first hole is designed as the first blind hole because the design of the first blind hole can make the connector 140 not need to extend to an outer surface of the circuit layer 130 and abut against the outer surface of the circuit layer 130. Such a design can greatly reduce the length of the connector 140, reduce the material used for the connector 140, and effectively save a manufacturing cost of the PCB 100.

In one embodiment, as shown in FIG. 2, the first hole is a first through hole. In practical applications, setting the first through hole in the circuit layer 130 is more convenient for operation. For example, when forming a through hole, it is only necessary to extend the through hole through the circuit layer 130. On the other hand, by forming the first through hole in the circuit layer 130, the contact between the connector 140 and the metal substrate 110 can be accurately observed through the first through hole.

In one embodiment, as shown in FIG. 5, a diameter of the first through hole is greater than a diameter of the through hole. In this case, the first through hole and the through hole are combined to form a “T”-shaped hole. The “T”-shaped hole allows the connector 140 to be buried in the “T”-shaped hole, which can make a surface of the PCB 100 smooth and aesthetic.

In one embodiment, as shown in FIG. 3, the metal substrate 110 is provided with a second hole. The second hole is communicated with the through hole. The connector 140 is provided in the second hole. One end of the connector 140 abuts against the metal substrate 110, and the other end of the connector 140 abuts against the circuit layer 130 to electrically connect the metal substrate 110 and the circuit layer 130.

In one embodiment, as shown in FIG. 3, the second hole is a second blind hole. An opening direction of the second blind hole is toward the insulating layer 120. It is understandable that a length of the connector 140 is longer than a depth of the through hole. When the connector 140 is placed in the through hole, a portion of the connector 140 extending out of the through hole extends into the second blind hole. In order to prevent the unstable connection between the connector 140 and the metal substrate 110 from causing the metal substrate 110 and the circuit layer 130 to be unable to be electrically connected, a size of the connector 140 should be slightly larger than a diameter of the second blind hole. The portion of the connector 140 extending into the second blind hole is interference-fitted with the second blind hole, which can effectively ensure the reliability of the connection between the connector 140 and the metal substrate 110.

In addition, the second hole is designed as the second blind hole because the design of the second blind hole can make the connector 140 not need to extend to an outer surface of the metal substrate 110 and abut against the outer surface of the metal substrate 110. Such a design can greatly reduce the length of the connector 140, reduce the material used for the connector 140, and effectively save a manufacturing cost of the PCB 100.

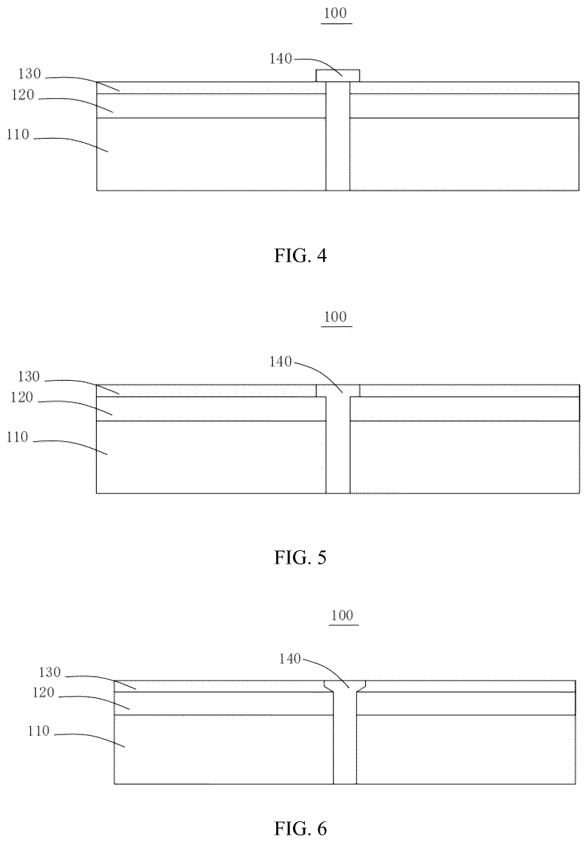

In one embodiment, as shown in FIG. 4 and FIG. 5, the second hole is a second through hole. In practical applications, the second through hole is provided on the metal substrate 110, which is more convenient for operation. For example, when the through hole is formed, it is only necessary to extend the through hole through the metal substrate 110. On the other hand, by forming the second through hole on the metal substrate 110, the contact between the connector 140 and the circuit layer 130 can be accurately observed through the second through hole.

In one embodiment, a diameter of the second through hole is larger than a diameter of the through hole. In this case, the second through hole and the through hole are combined to form a “T”-shaped hole. The “T”-shaped hole allows the connector 140 to be buried in the “T”-shaped hole, which can make a surface of the PCB 100 smooth and aesthetic.

In one embodiment, the connector 140 is a metal rivet. The metal rivet includes a rivet head and a rivet rod. The metal rivet is disposed in the through hole. The rivet head abuts against the circuit layer 130. The rivet rod abuts against the metal substrate 110 so that the metal substrate 110 and the circuit layer 130 are electrically connected.

In this embodiment, the metal rivet can be made of copper, aluminum, or alloy materials such as copper alloy, aluminum alloy, etc. Since metal has good thermal conductivity, the metal rivet can also conduct heat, so that the PCB 100 has good heat dissipation performance.

In addition, in this embodiment, the rivet head of the metal rivet is circular. It is conceivable that the rivet head of the metal rivet can also be in other shapes, such as square. It is understandable that a circular rivet head is more conducive to industrialization. However, it should be noted that no matter what shape the rivet head of the metal rivet is, it is only necessary to ensure the flatness of a surface where the rivet head contacts the circuit layer 130, ensure as much contact as possible between the metal rivet and the circuit layer 130, and ensure the reliability of the electrical connection between the circuit layer 130 and the metal substrate 110.

In one embodiment, as shown in FIG. 6, a surface of the rivet head in contact with the circuit layer 130 is an inclined surface, and a thickness of the rivet head gradually decreases from close to the rivet rod toward away from the rivet rod.

In this embodiment, the surface where the rivet head contacts the circuit layer 130 is the inclined surface. On the one hand, the inclined surface can increase a contact area between the metal rivet and the circuit layer 130, thereby ensuring the reliability of the electrical connection between the circuit layer 130 and the metal substrate 110. On the other hand, the inclined surface of the rivet head facilitates further embedding of the metal rivet in the through hole, which is beneficial to reducing a height difference between the metal rivet and the circuit layer 130, effectively increasing the flatness of the surface of the PCB 100, and making the PCB 100 more aesthetic.

In one embodiment, the connector 140 is made of the same material as the metal substrate 110, and the connector 140 and the metal substrate 110 are integrally formed.

The specific operations are as follows:

A fixing piece is placed on each side of a position on the PCB 100 where electrical connection is required. The fixing piece is placed on the circuit layer130. Then a top block is placed under the metal substrate 110 at a corresponding position. After pressing the fixing piece, a force is applied to the top block so that the top block punches out a part of the PCB 100 at the position on the PCB 100 where electrical connection is required. A height of the metal substrate 1 10 of the punched-out part of the PCB 100 is higher than the circuit layer 130. Finally, the top block is kept stationary and the fixing piece is removed. A pressing block is placed on an upper end of the punched-out part of the PCB 100. After a force is applied to the pressing block, the punched-out part of the PCB 100 is squeezed so that the metal substrate 1 10 of the punched-out part of the PCB 100 is deformed and moves toward both sides. Finally, the metal substrate 110 of the punched-out part of the PCB 100 is in contact with the circuit layer 130 to form an electrical connection.

In addition, a suitable pressing block is selected according to actual needs. For example, when a surface of the pressing block in contact with the punched-out part of the PCB 100 is a flat surface, the surface of the metal substrate 110 of the punched-out part of the PCB 100 in contact with the circuit layer 130 is a plane. For example, when the surface of the pressing block in contact with the punched-out part of the PCB 100 is a conical surface, the surface of the metal substrate 110 of the punched-out part of the PCB 100 in contact with the circuit layer 130 is an inclined surface.

As a second aspect of the embodiments of the present disclosure, an embodiment of the present disclosure provides a manufacturing method of a PCB 100, which is applicable to the PCB 100 of the above embodiments, and the method includes:
providing a metal substrate 110;
disposing an insulating layer 120 on the metal substrate 110, where the insulating layer 120 is provided with a through hole;
disposing a connector 140 in the through hole, where the connector 140 abuts against the metal substrate 110;
disposing a circuit layer 130 on a side of the insulating layer 120 away from the metal substrate 110, where the circuit layer 130 abuts against the connector 140 such that the metal substrate 110 and the circuit layer 130 are electrically connected.

As a third aspect of the embodiments of the present disclosure, an embodiment of the present disclosure provides a manufacturing method of a PCB 100, which is applicable to the PCB 100 of the above embodiments, and the method includes:
laminating a metal substrate 110, an insulating layer 120, and a circuit layer 130 in sequence to form a metal substrate PCB;
forming a through hole, where the through hole at least extends through the insulating layer 120;
disposing a connector 140 in the through hole, where the connector 140 abuts against the metal substrate 110 and the circuit layer 130 to electrically connect the metal substrate 110 and the circuit layer 130.

First, the metal substrate 110, the insulating layer 120, and the circuit layer 130 are laminated together in sequence to form the metal substrate PCB. The specific operation is as follows: the metal substrate 110 is adhered to a surface of the insulating layer 120 by an adhesive on the surface of the insulating layer 120. Then, a layer of the circuit layer 130 is covered on the other surface of the insulating layer 120 by an adhesive. The metal substrate 110, the insulating layer 120, and the circuit layer 130 adhered together by the adhesive are subjected to a laminating process again, so that the connection between the metal substrate 110, the insulating layer 120, and the circuit layer 130 is tighter to form a preliminary metal substrate PCB.

Secondly, a through hole is drilled or punched out at a location on the metal substrate PCB where electrical connection is required by using a tool (an appropriate tool is selected based on the user's operating habits, no specific requirements are given). The through hole at least extends through the insulating layer 120. For example, the through hole can extend through the insulating layer 120 and the circuit layer 130 without passing through the metal substrate 110. For example, the through hole can extend through the insulating layer 120 and the circuit layer 130, and pass through the metal substrate 110 to form a blind hole on the metal substrate 110. For example, the through hole can extend through the insulating layer 120 and the metal substrate 110 without passing through the circuit layer 130. For example, the through hole can extend through the insulating layer 120 and the metal substrate 110, and pass through the circuit layer 130 to form a blind hole on the circuit layer 130. For example, the through hole can extend through the insulating layer 120 and the circuit layer 130, and pass through the metal substrate 110 to form a through hole on the metal substrate 110. At this time, the through hole extends through the metal substrate 110, the insulating layer 120, and the circuit layer 130 at the same time.

Finally, the connector 140 is placed into the through hole. In order to ensure the stability of the connector 140, the connector 140 is interference fit with the through hole. Therefore, when the connector 140 is initially placed into the through hole, force needs to be applied to the connector 140. The connector 140 is pressed downward so that the connector 140 abuts against the circuit layer 130 and also contacts the metal substrate 110, and finally the metal substrate 110 and the circuit layer 130 are electrically connected.

In the above embodiments, the description of each embodiment has its own emphasis. For parts that are not described in detail in a certain embodiment, reference can be made to the relevant descriptions of other embodiments.

The above is a detailed introduction to the adhesive pasting equipment provided by the embodiments of the present application. The principles and implementation methods of the present application are described in detail using specific examples. The description of the above embodiments is only used to help understand the method and core idea of the present application. At the same time, for those skilled in the art, according to the idea of the present application, there will be changes in the specific implementation method and application scope. In summary, the content of this specification should not be understood as limiting the present application.

1. A printed circuit board (PCB), comprising:
a metal substrate;
an insulating layer disposed on a side of the metal substrate, and provided with a through hole;
a circuit layer disposed on a side of the insulating layer away from the metal substrate;
a connector disposed in the through hole to electrically connect the metal substrate and the circuit layer.

2. The PCB according to claim 1, wherein the circuit layer is provided with a first hole, the first hole is communicated with the through hole, the connector is disposed in the first hole, one end of the connector abuts against the metal substrate, and another end of the connector abuts against the circuit layer to electrically connect the metal substrate and the circuit layer.

3. The PCB according to claim 2, wherein the first hole is a first blind hole, and an opening direction of the first blind hole is toward the insulating layer.

4. The PCB according to claim 2, wherein the first hole is a first through hole.

5. The PCB according to claim 4, wherein a diameter of the first through hole is greater than a diameter of the through hole.

6. The PCB according to claim 1, wherein the metal substrate is provided with a second hole, the second hole is communicated with the through hole, the connector is disposed in the second hole, one end of the connector abuts against the metal substrate, and another end of the connector abuts against the circuit layer to electrically connect the metal substrate and the circuit layer.

7. The PCB according to claim 6, wherein the second hole is a second blind hole, and an opening direction of the second blind hole is toward the insulating layer.

8. The PCB according to claim 6, wherein the second hole is a second through hole.

9. The PCB according to claim 8, wherein a diameter of the second through hole is greater than a diameter of the through hole.

10. The PCB according to claim 1, wherein the connector is a metal rivet, the metal rivet comprises a rivet head and a rivet rod, the metal rivet is disposed in the through hole, the rivet head abuts against the circuit layer, and the rivet rod abuts against the metal substrate to electrically connect the metal substrate and the circuit layer.

11. The PCB according to claim 10, wherein a surface of the rivet head abutting against the circuit layer is an inclined surface, and a thickness of the rivet head gradually decreases from close to the rivet rod toward away from the rivet rod.

12. The PCB according to claim 1, wherein a material of the connector is the same as a material of the metal substrate.

13. The PCB according to claim 12, wherein the connector and the metal substrate are integrally formed.

14. A printed circuit board (PCB) manufacturing method for manufacturing a PCB, comprising:
providing a metal substrate;
disposing an insulating layer on the metal substrate, wherein the insulating layer is provided with a through hole;
disposing a connector in the through hole, wherein the connector abuts against the metal substrate;
disposing a circuit layer on a side of the insulating layer away from the metal substrate, wherein the circuit layer abuts against the connector such that the metal substrate and the circuit layer are electrically connected.

15. The PCB manufacturing method according to claim 14, wherein the circuit layer is provided with a first hole, the first hole is communicated with the through hole, the connector is disposed in the first hole, one end of the connector abuts against the metal substrate, and another end of the connector abuts against the circuit layer to electrically connect the metal substrate and the circuit layer.

16. The PCB manufacturing method according to claim 15, wherein the first hole is a first blind hole, and an opening direction of the first blind hole is toward the insulating layer.

17. The PCB manufacturing method according to claim 15, wherein the first hole is a first through hole.

18. The PCB manufacturing method according to claim 14, wherein the metal substrate is provided with a second hole, the second hole is communicated with the through hole, the connector is disposed in the second hole, one end of the connector abuts against the metal substrate, and another end of the connector abuts against the circuit layer to electrically connect the metal substrate and the circuit layer.

19. The PCB manufacturing method according to claim 17, wherein the second hole is a second blind hole, and an opening direction of the second blind hole is toward the insulating layer.

20. A printed circuit board (PCB) manufacturing method for manufacturing a PCB, comprising:
laminating a metal substrate, an insulating layer, and a circuit layer in sequence to form a metal substrate PCB;
forming a through hole, wherein the through hole at least extends through the insulating layer;
disposing a connector in the through hole, wherein the connector abuts against the metal substrate and the circuit layer to electrically connect the metal substrate and the circuit layer.
